(19) United States
(12) Patent Application Publication
(10) Pub. No.: US 2026/0271280 A1
(43) Pub. Date: Sep. 10, 2026

(54) SEMICONDUCTOR DEVICE INCLUDING FIRST AND SECOND STRUCTURES IN VERTICAL ARRANGEMENT

(71) Applicant: Samsung Electronics Co., Ltd., Suwon-si (KR)

(72) Inventors: Jaewan Ko, Suwon-si (KR); Jinwoo Han, Suwon-si (KR)

(73) Assignee: Samsung Electronics Co., Ltd., Suwon-si (KR)

(21) Appl. No.: 19/555,610

(22) Filed: Mar. 3, 2026

(30) Foreign Application Priority Data
Mar. 4, 2025 (KR) 10-2025-0027575

(51) Int. Cl. H10B 12/00

(52) U.S. Cl. CPC H10B 12/50; H10B 12/09; H10B 12/30

(57) ABSTRACT

Some embodiments provide a semiconductor device including a first structure including a substrate; and a second structure vertically overlapping the first structure and bonded to the first structure, wherein the first structure includes a memory cell structure disposed on the substrate; a first dummy plug spaced apart from the memory cell structure, electrically isolated from the memory cell structure, and extending in a vertical direction, on the substrate; and a first dummy interconnection structure connected to the first dummy plug, on the first dummy plug, and the second structure includes a semiconductor body; a second dummy plug penetrating the semiconductor body and connected to the first dummy interconnection structure; and an insulating spacer disposed between the semiconductor body and the second dummy plug.

### CROSS-REFERENCE TO RELATED APPLICATIONS

This present application claims priority to and the benefit under 35 U.S.C. §119(a)-(d) of Korean Patent Application No. 10-2025-0027575, filed on Mar. 4, 2025, in the Korean Intellectual Property Office, the entire disclosure of which is incorporated herein by reference.

### FIELD

The present disclosure relates to a semiconductor device and more particularly to a semiconductor device including first and second structures vertically arranged with respect to one another.

### BACKGROUND

Conventional semiconductor devices may be formed in two dimensions or in a planar manner, and in such a structure, an area occupied by a unit memory cell array may act as a major factor in determining a degree of integration of the device. Therefore, in order to implement a semiconductor device with a high degree of integration, the development of a fine pattern formation technology may be essential, and overcoming limitations of photolithography and etching processes has emerged as an important task. However, since it is difficult to further improve a degree of integration in a conventional two-dimensional structure due to a limitation of miniaturization, a three-dimensional semiconductor device including three-dimensionally arranged memory cells has been proposed as an alternative for solving this problem. However, in a three-dimensional structure, there is a possibility that heat may not be effectively dissipated due to the devices stacked as a plurality of layers, and accordingly, there may be a need for a semiconductor device and a manufacturing method, considering thermal characteristics.

### SUMMARY

As a means for solving the above-described problems, some example embodiments provide a semiconductor device comprising: a first structure including a substrate; and a second structure vertically overlapping the first structure and bonded to the first structure, wherein the first structure includes: a memory cell structure on the substrate; a first dummy plug spaced apart from the memory cell structure, electrically isolated from the memory cell structure, and extending in a vertical direction, on the substrate; and a first dummy interconnection structure connected to the first dummy plug, on the first dummy plug, and the second structure includes: a semiconductor body; a second dummy plug penetrating the semiconductor body and connected to the first dummy interconnection structure; and an insulating spacer between the semiconductor body and the second dummy plug.

Some example embodiments provide a semiconductor device comprising: a first structure including a semiconductor substrate; and a second structure on the first structure and including a semiconductor body, wherein the first structure includes: a memory cell structure on the semiconductor substrate; a first routing pattern on the memory cell structure, electrically connected to the memory cell structure, and extending in a vertical direction; a first routing interconnection electrically connected to the first routing pattern, on the first routing pattern; a first heat conduction pattern spaced apart from the memory cell structure in a horizontal direction, and extending in the vertical direction; and a first heat conduction interconnection connected to the first heat conduction pattern, on the first heat conduction pattern, the second structure includes: an upper insulating structure on the semiconductor body; a second routing interconnection embedded in the upper insulating structure; a second routing pattern extending in the vertical direction, below the second routing interconnection; a second heat conduction interconnection embedded in the upper insulating structure and spaced apart from the second routing interconnection in the horizontal direction; and a second heat conduction pattern extending in the vertical direction, below the second heat conduction interconnection, the second routing pattern penetrates the semiconductor body and is connected to the first routing interconnection to form an electric signal transmission path, and the second heat conduction pattern penetrates the semiconductor body and is connected to the first heat conduction interconnection to form a heat conduction path.

Some example embodiments provide a semiconductor device comprising: a first structure including a semiconductor substrate; and a second structure vertically overlapping the first structure and bonded to the first structure, wherein the first structure includes: channel structures extending in a first horizontal direction on the semiconductor substrate and spaced apart from each other in a second horizontal direction, intersecting the first horizontal direction and in a vertical direction, intersecting the first horizontal direction and the second horizontal direction; bit lines extending in the vertical direction on the semiconductor substrate, spaced apart from each other in the second horizontal direction, and contacting a first end portion of each of the channel structures; information storage structures contacting second end portions of the channel structures opposing the first end portions of the channel structures; gate electrodes surrounding the channel structures spaced apart from each other in the second horizontal direction, extending in the second horizontal direction, and including gate pads in a stepped structure; a first dummy plug contacting the semiconductor substrate and extending in the vertical direction; and a first dummy interconnection structure overlapping the first dummy plug in the vertical direction, and connected to the first dummy plug, and the second structure includes: a semiconductor body; an upper insulating structure on the semiconductor body; a second dummy interconnection structure embedded in the upper insulating structure; a dummy via extending in the vertical direction and contacting an upper surface of the semiconductor body, below the second dummy interconnection structure; and a second dummy plug extending in the vertical direction and penetrating the semiconductor body to be connected to the first dummy interconnection structure, below the second dummy interconnection structure.

A method of manufacturing a semiconductor device according to embodiments includes: forming a lower structure including a substrate on which a memory cell structure and a first dummy plug are disposed; forming an upper structure including a semiconductor body; bonding the lower structure and the upper structure to form a bonded structure; and forming a second dummy plug sequentially penetrating the bonded structure in a vertical direction to be spaced apart from the memory cell structure, and connected to the first dummy plug.

Forming the lower structure may include forming the first dummy plug on the substrate; and may include etching a portion of an upper surface of the lower structure to form a first dummy via hole spaced apart from the memory cell structure and exposing a portion of an upper surface of the substrate; and filling the first dummy via hole with a conductive material to form the first dummy plug.

Forming the first dummy plug on the substrate may include forming a contact plug electrically connected to the memory cell structure and extending in the vertical direction, on the memory cell structure, during forming the first dummy plug.

Forming the first dummy plug on the substrate may include forming the first dummy plug disposed on a level, lower than an upper surface of the substrate and having a lower surface contacting the substrate.

A side surface of the first dummy plug may include a side surface portion disposed on a level, lower than the upper surface of the substrate, and the side surface portion of the first dummy plug may be in contact with the substrate.

Forming the first dummy plug on the substrate may further include forming a first dummy plug contacting the substrate; and the forming a first dummy plug contacting the substrate may include partially etching the upper surface of the substrate, and filling the partially etched upper surface of the substrate with a conductive material.

Bonding the lower structure and the upper structure to form a bonded structure may include performing a plasma activation process on an upper surface of the lower structure; and performing positional alignment with respect to the lower structure and the upper structure.

Forming the upper structure including a semiconductor body may include forming peripheral transistors on an upper surface of the semiconductor body; forming an upper insulating layer covering the peripheral transistors on the semiconductor body; and forming peripheral vias connected to the peripheral transistors on the semiconductor body.

Forming the second dummy plug may include forming the first dummy plug and the second dummy plug to be spaced apart when viewed in the vertical direction.

### BRIEF DESCRIPTION OF THE DRAWINGS

The and other aspects, features, and advantages of the present inventive concept will be more clearly understood from the following detailed description, taken in conjunction with the accompanying drawings, in which:

FIG. 1 is a conceptual perspective view of a semiconductor device according to some embodiments.

FIG. 2 is a circuit diagram of a memory cell in a memory cell array region according to some embodiments.

FIG. 3 is a schematic plan view of a semiconductor device according to some embodiments.

FIG. 4 is a vertical cross-sectional view along line I-I′ of the semiconductor device illustrated in FIG. 3, and FIG. 5 is a partial enlarged view of portion ‘A’ of FIG. 4.

FIG. 6A is a vertical cross-sectional view along line II-II′ of the semiconductor device illustrated in FIG. 3, FIG. 6B is a partial enlarged view of portion ‘B’ of FIG. 6A, and FIG. 6C is a partial enlarged view of portion ‘C’ of FIG. 6A.

FIG. 7 is a vertical cross-sectional view along line III-III′ of the semiconductor device illustrated in FIG. 3.

FIG. 8 is a vertical cross-sectional view along line II-II′ of a semiconductor device according to some embodiments.

FIG. 9 is a vertical cross-sectional view along line II-II′ of a semiconductor device according to some embodiments.

FIG. 10 is a vertical cross-sectional view along line II-II′ of a semiconductor device according to some embodiments.

FIG. 11 is a vertical cross-sectional view along line III-III′ of a semiconductor device according to some embodiments.

FIG. 12 is a vertical cross-sectional view along line III-III′ of a semiconductor device according to some embodiments.

FIGS. 13A to 13I are cross-sectional views schematically illustrating a manufacturing process of a semiconductor device according to some embodiments.

### DETAILED DESCRIPTION

Hereinafter, preferred embodiments will be described with reference to the attached drawings. Unless otherwise specifically stated, in this specification, terms such as ‘on,’ ‘upper portion,’ ‘upper surface,’ ‘below,’ ‘lower portion,’ ‘lower surface,’ ‘side surface,’ or the like may be based on the drawings, and may actually vary depending on a direction in which components are disposed.

Additionally, ordinal numbers such as “first,” “second,” “third,” or the like may be used as labels for specific elements, operations, directions, or the like to distinguish between various elements, operations, directions, or the like. Terms that may not be described in the specification using “first,” “second,” or the like may still be referred to as “first” or “second” in the claims. Additionally, terms that may be referenced by a particular ordinal number (e.g., “first”′ in a particular claim) may be described elsewhere by a different ordinal number (e.g., “second” in the specification or another claim).

The present inventive concepts relate to a semiconductor device and/or a method of manufacturing the same.

One of problems to be solved by the technical idea of the present inventive concept is to efficiently improve heat conduction between an upper chip and a lower chip in a three-dimensional structure memory device. To this end, the present disclosure provides a semiconductor device capable of additionally forming a structure for heat conduction between the upper chip and the lower chip to facilitate heat dissipation and improve thermal stability of the device.

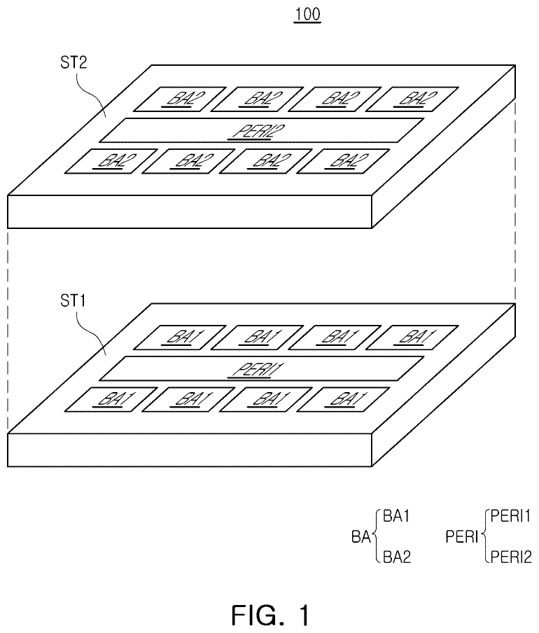

FIG. 1 is a conceptual perspective view of a semiconductor device according to embodiments.

Referring to FIG. 1, a semiconductor device 100 may include a first structure ST1 and a second structure ST2 vertically overlapping the first structure ST1. The second structure ST2 may be disposed on the first structure ST1.

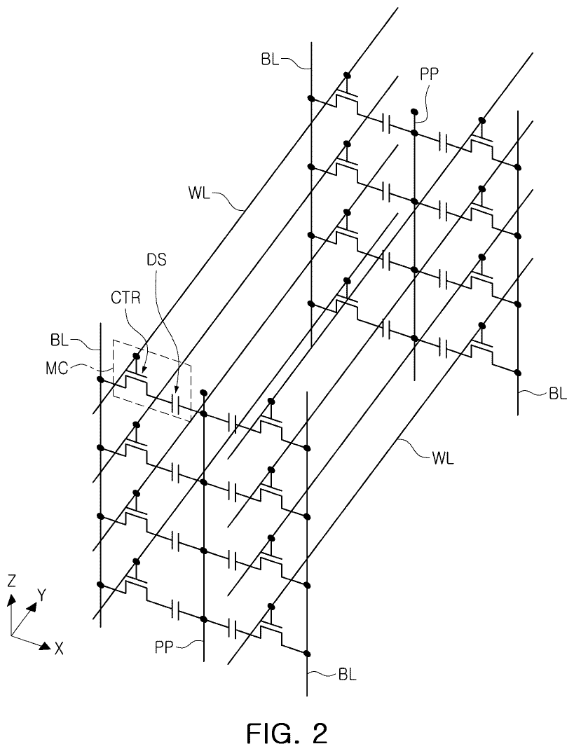

The first structure ST1 may be a first chip structure including memory cells (MC of FIG. 2), and the second structure ST2 may be a second chip structure including peripheral circuits capable of operating the memory cells (MC of FIG. 2). The first structure ST1 and the second structure ST2 may be bonded and formed by a bonding process such as a wafer bonding process. Therefore, the first structure ST1 may be in contact with and bonded to the second structure ST2.

The semiconductor device 100 may include a plurality of banks BA and a peripheral circuit region PERI. The peripheral circuit region PERI may include a first peripheral circuit region PERI1 in the first structure ST1, and a second peripheral circuit region PERI2 in the second structure ST2. The peripheral circuit region PERI may be a peripheral circuit region in which peripheral circuits for input/output of data or commands, or input of power/ground, are disposed.

Each of the plurality of banks BA may include a first bank region BA1 in the first structure ST1, and a second bank region BA2 in the second structure ST2.

The first bank region BA1 in the first structure ST1 may include memory cell array regions. The memory cell array regions may include memory cells (MC of FIG. 2). The memory cell array regions may be arranged in a first direction (X-direction) and a second direction (Y-direction). The first direction (X-direction) and the second direction (Y-direction) may be perpendicular to each other. The first direction (X-direction) and the second direction (Y-direction) may be referred to as horizontal directions, and a third direction (Z-direction) may be referred to as a vertical direction.

The second bank region BA2 in the second structure ST2 may include core circuit regions. The core circuit regions may be arranged in the first direction (X-direction) and the second direction (Y-direction). The core circuit regions may include sense amplifiers and sub-word line drivers.

The first peripheral circuit region PERI1 and the second peripheral circuit region PERI2 may include a control circuit capable of controlling the sense amplifiers and sub-word line drivers.

FIG. 2 is a circuit diagram of a memory cell in a memory cell array region according to embodiments.

Referring to FIG. 2, a memory cell array region may include memory cells MC arranged in the first direction (X-direction) and the second direction (Y-direction), word lines WL connected to the memory cells MC and extending in the second direction (Y-direction), and bit lines BL connected to the memory cells MC and extending in the vertical direction (Z-direction). Each of the memory cells MC may include a cell transistor CTR and information storage structures DS that may function as information storage.

The memory cells MC may have a structure in which two or more memory cells are stacked in the vertical direction (Z-direction). In an example, two memory cells MC may be disposed in the horizontal direction as one pair.

A gate of the cell transistor CTR may be connected to the word line WL, a first source/drain region of the cell transistor CTR may be connected to the bit line BL, and a second source/drain region of the cell transistor CTR may be connected to the information storage structure DS.

The cell transistor CTR and the information storage structures DS may be disposed in a horizontal arrangement extending in the first direction (X-direction). Adjacent information storage structures DS may share a plate electrode PP. The plate electrode PP may extend in the vertical direction (Z-direction) and be electrically connected to the information storage structures DS. The plate electrode PP may be vertically oriented. The plate electrode PP may be referred to as a vertical plate electrode. Two memory cells MC disposed in the horizontal direction as one pair may share one plate electrode PP. Each of the information storage structures DS and the plate electrode PP may function as a cell capacitor of each of the memory cells MC. The information storage structure DS and the plate electrode PP may be referred to as a capacitor structure.

The memory cells MC may be disposed between the bit lines BL and the plate electrode PP. The memory cells MC may be disposed in a horizontal arrangement in the first direction (X-direction). Each of the memory cells MC may be connected to one bit line of the bit lines BL, one word line of the word lines WL, and one plate electrode of the plate electrodes PP.

The word lines WL may be spaced apart from each other in the first direction (X-direction), and may extend in the second direction (Y-direction). The word lines WL may be arranged in the vertical direction (Z-direction). In an example, the word lines WL may be horizontally oriented with respect to a plane of the first structure ST1. The word lines WL may be referred to as horizontal word lines. A plurality of memory cells MC arranged horizontally in the second direction (Y-direction) may be connected to one word line WL.

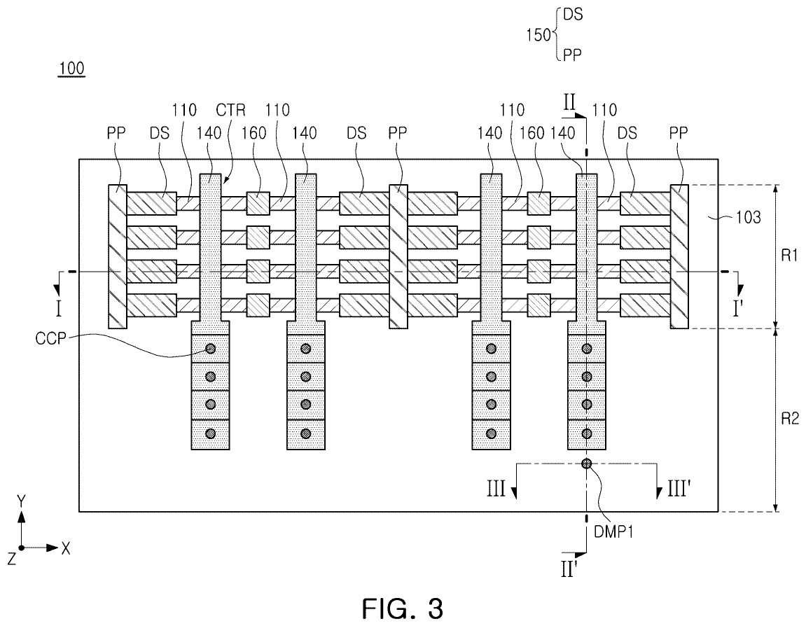

The bit lines BL may be spaced apart from each other in the second direction (Y-Attorney direction), and may extend in the third direction (Z-direction). The bit lines BL may be vertically oriented from a plane of the second structure ST2. The bit lines BL may be referred to as vertical bit lines. A plurality of memory cells MC arranged vertically in the third direction (Z-direction) may be connected to one bit line BL.
FIG. 3 is a schematic plan view of a semiconductor device according to an embodiment.

Referring to FIG. 3, a semiconductor device 100 may include a substrate 103 including a memory cell array region R1 and a stepped region R2, a cell transistor CTR, channel structures 110, a vertical conductive pattern 160, a capacitor structure 150, gate electrodes 140, a contact plug CCP, and a first dummy plug DMP1.

In an embodiment, the contact plug CCP may be referred to as a “first routing pattern” that may constitute a portion of an electrical signal transmission path.

In an embodiment, the first dummy plug DMP1 may be referred to as a “heat conduction pattern” that may constitute a portion of a heat dissipation path.

In the memory cell array region R1 of the substrate 103, the cell transistors CTR may be disposed between vertical conductive patterns 160 and capacitor structures 150. In the stepped region R2 of the substrate 103, the gate electrodes 140 extending from the memory cell array region R1 with different lengths may be disposed. The memory cell array region R1 and the stepped region R2 may be disposed side by side in the second direction (Y-direction). In the present document, the memory cell array region R1 may be referred to as a first region, and the stepped region R2 may be referred to as a second region.

The substrate 103 may include a semiconductor material, such as a group IV semiconductor, a group III-V compound semiconductor, or a group II-VI compound semiconductor. The substrate 103 may be provided as a bulk wafer or an epitaxial layer. For example, the substrate 103 may be bulk silicon or silicon-on-insulator (SOI). The substrate 103 may be a semiconductor substrate.

The cell transistor CTR may include channel structures 110, gate electrodes 140, and gate dielectric layers 142 disposed between the channel structures 110 and the gate electrodes 140. The cell transistor CTR may include a gate all around field effect transistor (GAA FET).

The channel structures 110 may include a plurality of channel structures extending in the first direction (X-direction) and spaced apart in the second direction (Y-direction) and the third direction (Z-direction). Although four channel structures 110 are illustrated to be disposed in the second direction (Y-direction) in the same plane (X-Y plane), it may not limited thereto, and may include three or fewer channel structures or five or more channel structures.

The channel structures 110 may include a semiconductor material, for example, silicon, germanium, or silicon-germanium.

The vertical conductive patterns 160 may include a plurality of vertical conductive patterns extending in the vertical direction (Z-direction) and spaced apart from each other in the second direction (Y-direction). The vertical conductive patterns 160 may be in contact with first end portions of the channel structures 110. Each of the vertical conductive patterns 160 may be in contact with first end portions of the channel structures 110 disposed in the vertical direction (Z-direction).

The vertical conductive patterns 160 may include doped polysilicon, a metal, a conductive metal nitride, a metal-semiconductor compound, a conductive metal oxide, conductive graphene, a carbon nanotube, or a combination thereof. For example, at least one of the vertical conductive patterns 160 may be formed of doped polysilicon, Al, Cu, Ti, Ta, Ru, W, Mo, Pt, Ni, Co, TiN, TaN, WN, NbN, TiAl, TiAIN, TiSi, TiSIN, TaSi, TaSiN, RuTiN, NiSi, CoSi, IrOx, RuOx, graphene, carbon nanotubes, or a combination thereof. Each of the vertical conductive patterns 160 may correspond to the bit line BL of FIG. 2.

The capacitor structure 150 may include information storage structures DS and plate electrodes PP connected to the information storage structures DS.

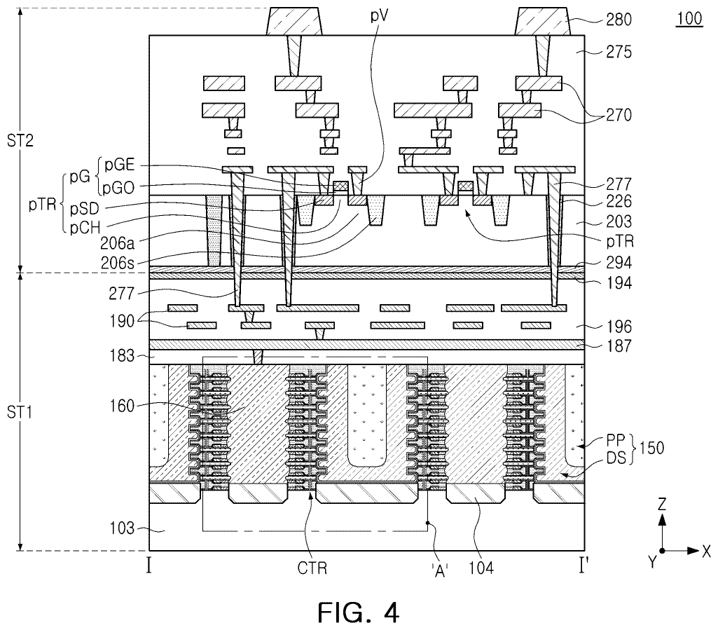

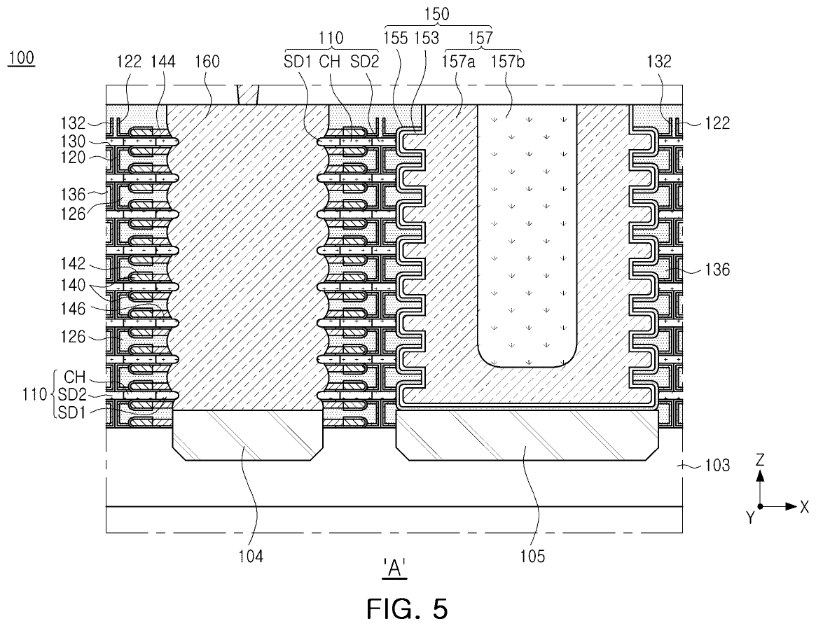

The information storage structures DS may be in contact with second end portions opposing the first end portions of the channel structures 110. The plate electrode PP will be described in detail in related descriptions of FIG. 4 below.

The gate electrodes 140 may surround the channel structures 110 disposed between the vertical conductive patterns 160 and the information storage structures DS. Each of the gate electrodes 140 may be disposed as a gate all around structure surrounding the channel structures 110. The gate electrodes 140 may extend in the second direction (Y-direction), and may be spaced apart from each other in the vertical direction (Z-direction). Each of the gate electrodes 140 may surround the channel structures 110 spaced apart in the second direction (Y-direction) on the same plane (X-Y plane). Each of the gate electrodes 140 may correspond to the word line WL of FIG. 2.

The gate electrodes 140 may be stacked vertically spaced apart from each other on the memory cell array region R1, and may extend from the memory cell array region R1 to the stepped region R2 at different lengths to form a step-shaped stepped structure. The gate electrodes 140 may form a stepped structure between the gate electrodes 140 spaced apart in the third direction (Z-direction) in the second direction (Y-direction). Due to the stepped structure, the gate electrodes 140 may have regions in which a gate electrode 140 in a lower portion extends to be longer than a gate electrode 140 in an upper portion, to be exposed upwardly from an interlayer insulating layer 145 and to contact the contact plug CCP. In an example, a stepped structure may be formed by a second gate electrode, a fourth gate electrode, and a sixth gate electrode, disposed below an uppermost gate electrode, among the gate electrodes 140, a stepped structure may be formed by overlapping a third gate electrode disposed below the uppermost gate electrode with the second gate electrode, and overlapping a fifth gate electrode disposed below the uppermost gate electrode with the fourth gate electrode. However, the present inventive concept is not limited thereto, and each of the gate electrodes 140 disposed below the uppermost gate electrode may form a stepped structure, and for example, the third gate electrode disposed below the uppermost gate electrode may extend to be longer than the second gate electrode disposed below the uppermost gate electrode to form a stepped structure.

Gate pads may be formed on an upper surface of the second gate electrode, an upper surface of the fourth gate electrode, and an upper surface of the sixth gate electrode, disposed below the uppermost gate electrode among the gate electrodes 140. The contact plugs CCP may be disposed on the gate pads.

When viewed in the vertical direction (Z-direction), the first dummy plug DMP1 may be disposed to be parallel to the contact plugs CCP, but spaced apart in the second direction (Y-direction). The first dummy plug DMP1 may not be connected to the gate pads of the gate electrodes 140. The first dummy plug DMP1 may be spaced apart from the contact plugs CCP. The first dummy plug DMP1 may be formed to have an interval, equal to an interval between the contact plugs CCP. The first dummy plug DMP1 may be disposed in the second region R2. The first dummy plug DMP1 may be disposed on the substrate 103. Although not illustrated, a plurality of first dummy plugs DMP1 may be disposed in the second region R2.

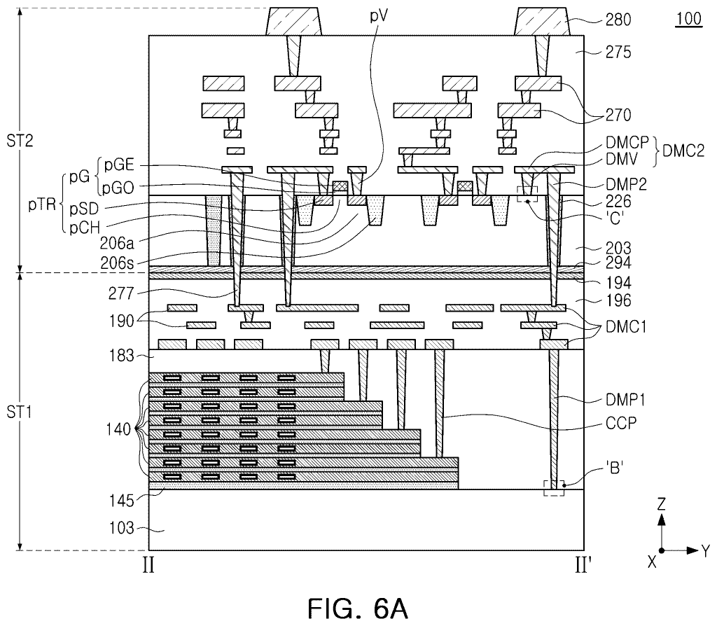

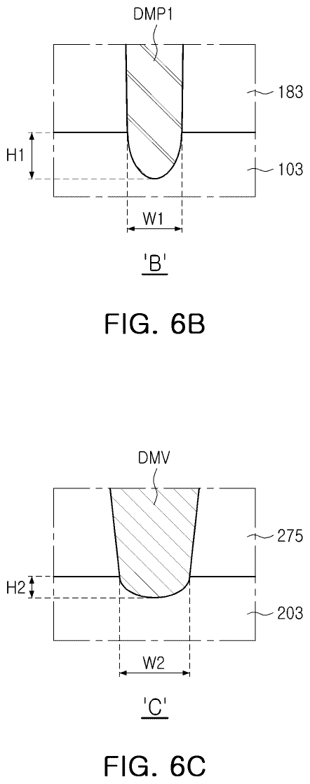

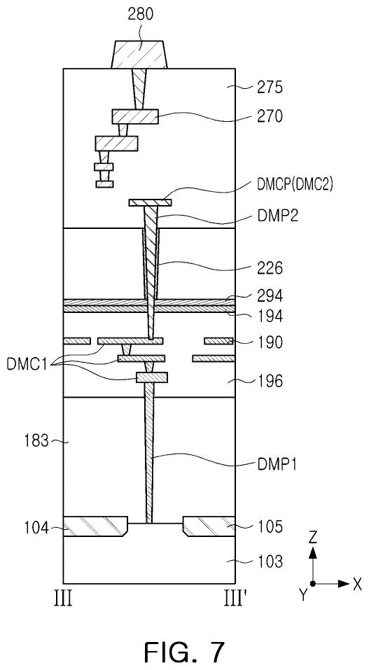

FIG. 4 is a vertical cross-sectional view along line I-I′ of the semiconductor device illustrated in FIG. 3, and FIG. 5 is a partial enlarged view of portion ‘A’ of FIG. 4. FIG. 6A is a vertical cross-sectional view along line II-II′ of the semiconductor device illustrated in FIG. 3, FIG. 6B is a partial enlarged view of portion ‘B’ of FIG. 6A, and FIG. 6C is a partial enlarged view of portion ‘C’ of FIG. 6A. FIG. 7 is a vertical cross-sectional view along line III-III′ of the semiconductor device illustrated in FIG. 3.

Referring to FIGS. 4 to 7, a semiconductor device 100 may include a first structure ST1 and a second structure ST2 vertically overlapping the first structure ST1. The first structure ST1 may be an example of the first structure ST1 described in FIG. 1, and the second structure ST2 may be an example of the second structure ST2 described in FIG. 1.

The first structure ST1 may be a memory region including memory cells disposed three-dimensionally, and the second structure ST2 may be a peripheral region including a peripheral circuit.

The first structure ST1 may include a substrate 103, and cell transistors CTR, vertical conductive patterns 160, and capacitor structures 150, disposed on the substrate 103.

The capacitor structures 150 of the first structure ST1 may be spaced apart from each other in the first direction (X-direction). One vertical conductive pattern 160 of the vertical conductive patterns 160 may be disposed between a pair of adjacent capacitor structures 150.

The first structure ST1 may include channel structures 110 that may be spaced apart from each other in the vertical direction (Z-direction), and may be stacked. Each of the channel structures 110 may include a first source/drain region SD1 adjacent to the vertical conductive pattern 160, a second source/drain region SD2 adjacent to the capacitor structure 150, and a channel region CH disposed between the first source/drain region SD1 and the second source/drain region SD2.

The first structure ST1 may include gate electrodes 140 stacked to be spaced apart from each other in the vertical direction (Z-direction). The gate electrodes 140 may overlap a channel region CH of the channel structures 110 in the vertical direction (Z-direction). Each of the gate electrodes 140 may surround the channel region CH, and may extend in the second direction (Y-direction).

The first structure ST1 may further include gate electrodes 140, interlayer insulating layers 145, a gate dielectric layer 142, a gate capping layer 144, and a gate insulating layer 146.

The semiconductor device 100 may include interlayer insulating layers 145 between gate electrodes 140 stacked to be spaced apart from each other in the vertical direction (Z-direction), and may electrically insulate gate electrodes 140 adjacent in the vertical direction (Z-direction). The interlayer insulating layers 145 may include an insulating material, for example, at least one of silicon nitride, silicon oxynitride, or silicon oxycarbide.

The semiconductor device 100 may include a gate dielectric layer 142 disposed between the channel structures 110 and the gate electrodes 140. The gate dielectric layer 142 may cover an upper surface, a lower surface, and a side surface of each of the channel structures 110. The gate dielectric layer 142 may include at least one of silicon oxide, silicon nitride, a low-k material, or a high-k material. The high-material may mean a dielectric material having a higher dielectric constant than silicon oxide, and the low-k material may mean a dielectric material having a lower dielectric constant than silicon oxide. The high-k material may be, for example, a metal oxide or a metal oxynitride. The high-k material may be, for example, one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), or praseodymium oxide (Pr₂O₃). The gate dielectric layer 142 may be formed as a single layer or a plurality of layers of the above-described materials.

The gate dielectric layer 142 may be disposed between the gate electrodes 140 and the channel structures 110. The gate dielectric layer 142 may be disposed in a gate all-around structure surrounding the channel structure 110, and may cover an upper surface, a lower surface, and a side surface of the gate electrode 140.

The gate capping layer 144 may be disposed between the gate electrode 140 and the vertical conductive pattern 160. A portion of the gate dielectric layer 142 may be disposed between the gate capping layer 144 and the channel structure 110. The gate insulating layer 146 may be disposed between the gate capping layer 144 and the first source/drain region SD1 of the channel structure 110.

The gate capping layer 144 may include an insulating material, for example, at least one of silicon nitride, silicon oxynitride, or silicon oxycarbide.

The first structure ST1 may further include a first buffer layer 120, a first liner 122, and a first gapfill insulating layer 126, disposed between the channel structures 110. The first buffer layer 120, the first liner 122, and the first gapfill insulating layer 126 may be in contact with the gate dielectric layer 142. For example, the first buffer layers 120 may extend horizontally on upper and lower surfaces of the channel structures 110, and may extend vertically (Z-direction) between the channel structures 110.

The first liner 122 may be conformally disposed on the first buffer layer 120.

The first gapfill insulating layer 126 may fill a space between adjacent gate dielectric layers 142. The first gapfill insulating layer 126 may be in contact with the gate capping layer 144 and the vertical conductive pattern 160. The first buffer layer 120 and the first gapfill insulating layer 126 may include silicon oxide, and the first liner 122 may include silicon nitride.

The first structure ST1 may further include a second buffer layer 130, a second liner 132, and a second gapfill insulating layer 136, disposed between the channel structures 110. In an example, the second buffer layer 130, the second liner 132, and the second gapfill insulating layer 136 may be in contact with a first electrode 155 of the capacitor structure 150. For example, the second buffer layers 130 may extend horizontally on the upper and lower surfaces of the channel structures 110, and may extend between the channel structures 110 in the vertical direction (Z-direction). The second liner 132 may be conformally disposed on the second buffer layer 130, and the second gapfill insulating layer 136 may be disposed on the second liner 132, and may fill a space between adjacent channel structures 110 and a space between the first electrodes 155. The first gapfill insulating layer 126 and the second gapfill insulating layer 136 may correspond to an interlayer insulating layer 145 of FIG. 6. The second buffer layer 130 and the second gapfill insulating layer 136 may include silicon oxide, and the second liner 132 may include silicon nitride.

The vertical conductive patterns 160 may extend in the vertical direction (Z-Attorney direction) on the substrate 103. The vertical conductive patterns 160 may be disposed to be spaced apart from each other in the first direction (X-direction) and the second direction (Y-direction). Channel structures 110 stacked in the vertical direction (Z-direction) on one vertical conductive pattern 160 may be electrically connected. For example, the vertical conductive patterns 160 may be electrically connected to the first source/drain regions SD1 of the channel structures 110.

Each of the capacitor structures 150 may include first electrodes 155, a second electrode 157, and a dielectric layer 153 disposed between the first electrodes 155 and the second electrode 157.

The first electrodes 155 may be electrically connected to the second source/drain regions SD2 of the channel structures 110. Each of the first electrodes 155 may have a cylinder shape oriented in the horizontal direction.

The second electrode 157 may include a 2-1 electrode material layer 157a contacting the dielectric layer 153 and a 2-2 electrode material layer 157b contacting the 2-1 electrode material layer 157a.

The dielectric layer 153 may be disposed between the first electrode 155 and the 2-1 electrode material layer 157a, and may conformally cover an inner wall of the first electrodes 155, and may extend from the inner wall of the first electrodes 155 in the vertical direction (Z-direction) to conformally cover a space between the first electrodes 155. The 2-1 electrode material layer 157a may be disposed on the inner wall of the first electrodes 155 on the dielectric layer 153. The 2-2 electrode material layer 157b may be disposed on the 2-1 electrode material layer 157a, and may be disposed to extend in the vertical direction (Z-direction) between the first electrodes 155 spaced apart in the horizontal direction.

The first electrode 155 and the second electrode 157 may include a metal, a metal oxide, a metal nitride, a metal carbide, a metal silicide, or a combination thereof. The dielectric layer 153 may be referred to as a capacitor dielectric layer, and may include silicon oxide, silicon nitride, a high-k material, or a combination thereof. The high-k material may have a higher permittivity than silicon oxide.

The first electrode 155, the dielectric layer 153, and the 2-1 electrode material layer 157a may constitute the information storage structures DS of FIG. 3. The 2-1 electrode material layer 157a and the 2-2 electrode material layer 157b may represent the plate electrode PP of FIG. 3, and the 2-2 electrode material layer 157b may have substantially the same shape as the plate electrode PP of FIG. 3, but an embodiment is not limited thereto.

Structures related to an operation of the memory cell MC, such as the cell transistor CTR, the vertical conductive pattern 160, the capacitor structure 150, the gate electrodes 140, the interlayer insulating layers 145, the gate dielectric layer 142, the gate capping layer 144, the gate insulating layer 146, the first buffer layers 120, the first liner 122, the first gapfill insulating layer 126, the second buffer layers 130, the second liner 132, and the second gapfill insulating layer 136, may be collectively referred to as a memory cell structure.

The first structure ST1 may further include element isolation structures 104, 105, and 106 disposed in the substrate 103.

The element isolation structures may include first element isolation patterns 104 contacting a lower surface of each of the vertical conductive patterns 160, second element isolation patterns 105 contacting lower surfaces of the capacitor structures 150, and third element isolation patterns 106 disposed between the first element isolation patterns 104 and the second element isolation patterns 105, and disposed below an insulating pattern disposed between information storage structures (e.g., information storage structures DS of FIG. 3)) and between channel structures 110.

The first element isolation pattern 104 may be disposed to extend in the second direction (Y-direction) from the substrate 103, and may overlap the vertical conductive patterns 160 in the vertical direction (Z-direction).

The second element isolation pattern 105 may be disposed to extend in the second direction (Y-direction) from the substrate 103, and may overlap the plate electrode PP in the vertical direction (Z-direction). The second element isolation pattern 105 may be spaced apart from the first element isolation pattern 104 in the first direction (X-direction) with the third element isolation patterns 106 interposed therebetween.

Each of the first element isolation pattern 104 and the second element isolation pattern 105 may extend in the second direction (Y-direction), and may be disposed across the stepped region R2 from the memory cell array region R1.

The third element isolation patterns 106 may be disposed to extend in the first direction (X-direction) from the substrate 103, and may overlap the insulating pattern (the first and second gap-fill insulating layers 126 and 136 of FIG. 5) disposed between the channel structures 110.

The first element isolation pattern 104, the second element isolation pattern 105, and the third element isolation pattern 106 may include the same insulating material. For example, the insulating material may include silicon oxide, silicon nitride, silicon oxynitride, silicon carbonitride, a low-k dielectric, or a combination thereof.

The first structure ST1 may further include an insulating layer 183 covering the vertical conductive patterns 160 and the capacitor structures 150, contact plugs 185 penetrating the insulating layer 183 and connected to the vertical conductive patterns 160, and conductive lines 187 disposed on the insulating layer 183 and connected to the contact plugs 185.

The conductive lines 187 may extend in the first direction (X-direction). The conductive line 187 may electrically connect the vertical conductive patterns 160 arranged in the first direction (X-direction) through the contact plugs 185.

The first structure ST1 may further include an insulating structure 196 on the conductive line 187, interconnection structures 190 embedded in the insulating structure 196, and a first bonding insulating layer 194.

In an embodiment, the interconnection structures 190 may be referred to as a “first routing interconnection” that may constitute a portion of an electric signal transmission path.

Referring to FIG. 6A, the first structure ST1 may include a first dummy plug DMP1 and a first dummy interconnection structure DMC1.

In an embodiment, the first dummy interconnection structure DMC1 may be referred to as a “first heat conduction interconnection” that may constitute a portion of a heat dissipation path.

Referring to FIGS. 6A and 6B, the first dummy plug DMP1 may be in contact with the substrate 103, and may extend in the vertical direction. The first dummy plug DMP1 may have a horizontal width decreasing in a direction facing the substrate 103 in the first structure ST1. The horizontal width of the first dummy plug DMP1 may decrease toward a lower surface contacting the substrate 103 from an upper surface contacting the first dummy interconnection structure DMC1. The first dummy plug DMP1 may have the lower surface contacting the upper surface of the substrate 103. In an embodiment, a portion of a lower end of the first dummy plug DMP1 may partially penetrate the substrate 103 to form a first groove having a first depth H1. In this case, a level of the lower surface of the first dummy plug DMP1 may be lower than a level of the upper surface of the substrate 103.

A length of the first dummy plug DMP1 in the vertical direction (Z-direction) may be longer than a length of a longest contact plug CCP among the contact plugs CCP. In an embodiment, the contact plugs CCP may be respectively formed on the gate pads, and a level of lower surfaces of the contact plugs CCP may be higher than a level of the gate pads. A level of a lower surface of the first dummy plug DMP1 may be lower than a level of an upper surface of a lowest gate pad among the gate pads. However, the present inventive concept is not limited thereto.

The second structure ST2 may include a peripheral circuit such as a sense amplifier, a sub-word line driver, or the like, in the second bank region BA2 described in FIG. 1. For example, the second structure ST2 may include peripheral transistors pTR that may configure the peripheral circuit. For example, the first source/drain regions SD1 of the cell transistor CTR disposed in the first structure ST1 may be electrically connected to the peripheral transistor pTR that may constitute a sense amplifier disposed in the second structure ST2 through the vertical conductive pattern 160 and the conductive line 187. In an example, an electrical connection relationship between the peripheral transistors pTR and the cell transistor CTR is illustrative, and embodiments are not limited to the structure disposed in FIG. 5.

The second structure ST2 may further include a semiconductor body 203, a peripheral device isolation region 206s defining a peripheral active region 206a on the semiconductor body 203, peripheral source/drain regions pSD disposed in the peripheral active region 206a, peripheral vias pV connected to the peripheral source/drain regions PSD, a peripheral channel region pCH between the peripheral source/drain regions pSD, or a peripheral gate pG including a peripheral gate dielectric layer pGO and a peripheral gate electrode pGE, sequentially disposed on the peripheral channel region pCH.

In an embodiment, the peripheral via pV may be referred to as a “routing via” that may constitute a portion of an electrical signal transmission path.

Each of the peripheral transistors pTR may include the peripheral source/drain regions pSD, the peripheral channel region pCH, and the peripheral gate pG.

The second structure ST2 may further include through-plugs 277 penetrating the semiconductor body 203 and electrically connecting peripheral interconnection structures 270 and a redistribution structure 290, and insulating spacers 226 on the side surfaces of the through-plugs 277.

In an embodiment, the peripheral interconnection structures 270 may be referred to as a “second routing interconnection” that may constitute a portion of an electrical signal transmission path.

In an embodiment, the through-plugs 277 may be referred to as “second routing patterns” that may constitute a portion of an electrical signal transmission path.

The peripheral transistor pTR may be connected to the peripheral via pV, and the peripheral via pV may be connected to the peripheral interconnection structure 270. The peripheral interconnection structure 270 may be connected to the through-plug 277, and may be connected to the interconnection structure 190 and the first dummy plug DMP1. The peripheral interconnection structure 270 may be in contact with the through-plug 277, and may be in contact with the peripheral via pV.

The second structure ST2 may further include a second bonding insulating layer 294 below the semiconductor body 203.

The first bonding insulating layer 194 may be bonded and connected to the second bonding insulating layer 294. The first and second bonding insulating layers 194 and 294 may include at least one of, for example, SiO, SiN, SiCN, SiOC, SiON, or SiOCN.

The first structure ST1 and the second structure ST2 may be bonded by bonding the first bonding insulating layer 194 and the second bonding insulating layer 294. Bonding of the first bonding insulating layer 194 and the second bonding insulating layer 294 may be, for example, a dielectric-dielectric bonding such as SiCN—SiCN bonding. The first structure ST1 and the second structure ST2 may be bonded only by the bonding of the first and second bonding insulating layers 194 and 294.

The second structure ST2 may further include an upper insulating structure 275 on the semiconductor body 203, a peripheral interconnection structure 270 embedded in the upper insulating structure 275 and electrically connected to the peripheral transistors pTR constituting the peripheral circuit, a second dummy interconnection structure DMC2 spaced apart from the peripheral interconnection structure 270 and embedded in the upper insulating structure 275, and upper interconnections 280 on the upper insulating structure 275

The second structure ST2 may further include a second dummy interconnection structure DMC2 and a second dummy plug DMP2.

In an embodiment, the second dummy interconnection structure DMC2 may be referred to as a “second heat conduction interconnection” that may constitute a portion of a heat dissipation path.

In an embodiment, the second dummy plug DMP2 may be referred to as a “second heat conduction pattern” that may constitute a portion of a heat dissipation path.

The second dummy interconnection structure DMC2 may be disposed on the semiconductor body 203 and embedded in the upper insulating structure 275.

The second dummy interconnection structure DMC2 may include a dummy interconnection pad DMCP and a dummy via DMV.

In an embodiment, the dummy via DMV may be referred to as a “heat conduction via” that may constitute a portion of a heat dissipation path.

The dummy interconnection pad DMCP may have a lower surface contacting an upper surface of the second dummy plug DMP2. The dummy interconnection pad DMCP may be disposed at a lowermost layer in the second dummy interconnection structure DMC2. However, the present inventive concept is not limited thereto, and although not illustrated, the dummy interconnection pad DMCP may be disposed in an intermediate portion in the second dummy interconnection structure DMC2.

The dummy via DMV may connect the dummy interconnection pad DMCP to the semiconductor body 203. The dummy via DMV may have an upper surface contacting a lower surface of the dummy interconnection pad DMCP. The dummy via DMV may be disposed to be spaced apart from the second dummy plug DMP2. An upper surface with which the dummy via DMV is in contact, and an upper surface on which the second dummy plug DMP2 is disposed may be spaced apart.

The dummy via DMV may be in contact with an upper surface of the semiconductor body 203. Referring to FIGS. 6A and 6C, a portion of a lower end of the dummy via DMV may partially penetrate the semiconductor body 203 to form a second groove having a second depth H2, shallower than the first depth H1 of the first groove formed by the first dummy plug DMP1.

Referring to FIGS. 6B and 6C, the second groove of the dummy via DMV may have a width W2 of the second groove, wider than a width W1 of the first groove of the first dummy plug DMP1. A portion of the lower end of the dummy via DMV may partially penetrate the semiconductor body 203 to form the second groove having the second width W2, narrower than the first width W1 of the first groove formed by the first dummy plug DMP1. The first dummy plug DMP1 may be formed to be longer than the dummy via DMV in the vertical direction. The width W1 of the lower end with which the first dummy plug DMP1 and the substrate are in contact may be formed smaller than the width W2 of the lower end with which the dummy via DMV and the semiconductor body 203 are in contact, in the horizontal direction. The first groove may be formed to have a narrow width in the horizontal direction and a deep depth in the vertical direction, and the second groove may be formed to have a wide width in the horizontal direction and a shallow depth in the vertical direction. The first groove may function as a portion of a passage through which heat moves by connecting the first dummy plug DMP1 to the substrate 103. The second groove may function as a portion of a passage through which heat moves by connecting the dummy via DMV to the semiconductor body 203.

The second dummy plug DMP2 may extend vertically below the second dummy interconnection structure DMC2, and may be connected to the first dummy interconnection structure DMC1 by penetrating the semiconductor body 203 and the first and second bonding insulating layers 194 and 294. In this case, the second dummy plug DMP2 may be directly connected to the first dummy interconnection structures DMC1 of the first structure ST1. However, the present inventive concept is not limited thereto. The second dummy plug DMP2 may penetrate the semiconductor body 203, and may connect the second dummy interconnection structure DMC2 and the first dummy interconnection structure DMC1. The second dummy plug DMP2 may further include an insulating spacer 226 on a side surface. The second dummy plug DMP2 may be electrically insulated from the semiconductor body 203 by the insulating spacer 226. In addition, the second dummy plug DMP2 may be electrically isolated.

For example, as a high speed of a DRAM progresses, to increase a response speed of a sense amplifier included in the peripheral circuit region PERI, power consumption may increase, and accordingly, heat generation may also increase. In a peri-over-cell (POC) structure, heat generated from the sense amplifier included in the peripheral circuit region PERI of the first structure ST1 may move to the first structure ST1 through the first and second dummy plugs DMP1 and DMP2. In general, various circuit blocks may operate in the peripheral circuit region PERI of the first structure ST1, and considerable heat may be generated, especially in high-speed signal processing circuits, power conversion circuits, or the like. In addition, complex operations such as memory interfaces may be performed, which increases power consumption and generates heat of a high temperature. Since the second structure ST2 generates relatively less heat, the first and second dummy plugs DMP1 and DMP2 may be disposed to disperse heat condensed on the semiconductor body 203 to the substrate 103. Through this, a phenomenon of local heat accumulation in the first structure ST1 may be alleviated. In particular, the first and second dummy plugs DMP1 and DMP2 formed of a metal material may have high thermal conductivity, such that the heat generated in the second structure ST2 may be quickly transferred to the first structure ST1 and effectively released externally. Through this, a temperature of the semiconductor body 203 of the second structure ST2 including the peripheral circuit region may be lowered, and circuit damage or reliability degradation problems that may occur due to a high temperature may be prevented. In addition, since heat may be uniformly distributed, formation of heat concentration (hot spot) in the second structure ST2 may be suppressed, and long-term device life extension and stable operation may be ensured. For this reason, arranging the first and second dummy plugs DMP1 and DMP2 between the first structure ST1 and the second structure ST2 may improve reliability of the semiconductor device.

Referring to FIGS. 6A and 6C, the second dummy plug DMP2 may be in contact with the semiconductor body 203, and may extend in the vertical direction. The second dummy plug DMP2 may have a width decreasing in a direction toward the first structure ST1 in the second structure ST2. A horizontal width of the second dummy plug DMP2 may decrease toward a lower surface contacting the semiconductor body 203 from an upper surface contacting the second dummy interconnection structure DMC2. For example, a width of an upper surface of the second dummy plug may be between about 50 nm and 80 nm, and a width of a lower surface of the second dummy plug may be between about 30 nm and 45 nm. Specifically, the width of the upper surface of the second dummy plug may be between about 60 nm and 70 nm, and the width of the lower surface of the second dummy plug may be between about 40 nm and 43 nm.

When the width of the upper surface of the second dummy plug DMP2 is about 80 nm or more, or the width of the lower surface of the second dummy plug DMP2 is about 45 nm or more, it becomes difficult to form the second dummy plug DMP2 in the insulating spacer 226, and the second dummy plug DMP2 may be in contact with the semiconductor body 203 beyond the insulating spacer 226. In a semiconductor device including the second dummy plug DMP2 in the defined numerical range, insulating characteristics of the insulating spacer 226 may be improved. Reliability of the second structure ST2 may be significantly improved. When the width of the second dummy plug DMP2 is within the defined numerical range, insulating characteristics may be improved, and as a result, electrical performance of the device may be stable, and possibility of extending a lifespan may increase.

When the width of the upper surface of the second dummy plug DMP2 is about 50 nm or less, or the width of the lower surface is about 30 nm or less, a thermal path may be limited to reduce heat dissipation efficiency of the second structure ST2, which may increase a temperature of the semiconductor device. When it is within the defined numerical range, heat dissipation may be properly performed and electrical characteristics may be maintained, and for example, leakage current may be prevented from occurring at high temperatures, thereby improving performance. In addition, the second dummy plug DMP2 in the defined numerical range may prevent formation of heat concentration (hot spot), thereby preventing a rapid increase in temperature in a specific region. As a result, reliability of the device may be significantly improved in the long term.

The second dummy plug DMP2 may have a lower surface contacting an upper surface of the semiconductor body 203. In an embodiment, a portion of a lower end of the second dummy plug DMP2 may partially penetrate the semiconductor body 203 to form a second groove having a second depth H2. In this case, a level of the lower surface of the second dummy plug DMP2 may be lower than a level of the upper surface of the semiconductor body 203.

When the DRAM is packaged, the first structure ST1 on which the memory cell structure is disposed may be disposed to face an external space, not a PCB substrate. In this case, heat generated in the peripheral circuit region PERI of the second structure ST2 may be released externally through the substrate 103 of the first structure ST1 via the first and second dummy plugs DMP1 and DMP2. The first and second dummy plugs DMP1 and DMP2 may secure a heat conduction path in the first and second structures ST1 and ST2 to help heat generated in the peripheral circuit region PERI to be effectively dispersed. This may entirely prevent overheating of the peripheral circuit region PERI and improve reliability of a semiconductor module. As a result, thermal management of the DRAM may be optimized, thereby improving long-term operational stability and enhancing reliability of the device.

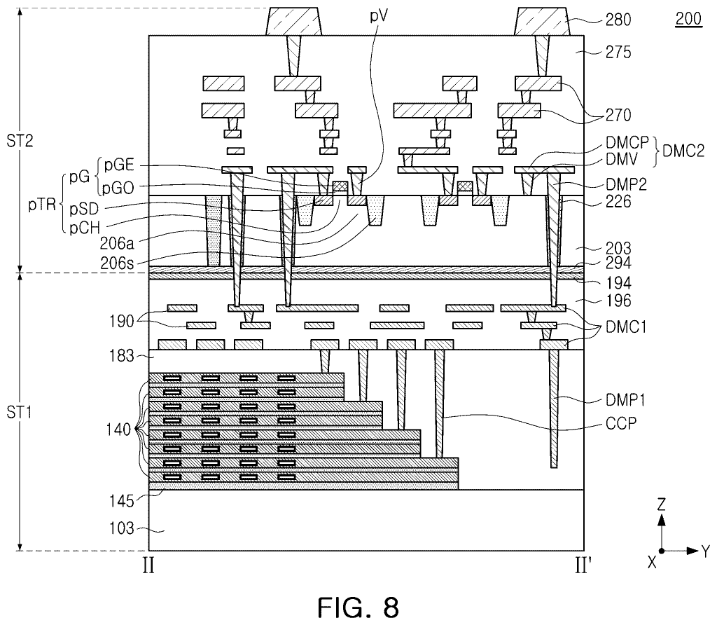

FIG. 8 is a vertical cross-sectional view along line II-II′ of a semiconductor device according to an embodiment.

Referring to FIG. 8, it can be understood that a semiconductor device 200 has a structure similar to that of the semiconductor device 100 illustrated in FIGS. 4 to 7, except that a first dummy plug DMP1 is not in direct contact with a substrate 103. Therefore, description of the semiconductor device 100 illustrated in FIGS. 4 to 7 may be combined with description of the semiconductor device 200 according to the present embodiment, unless otherwise stated.

In an embodiment, contact plugs CCP and a first dummy plug DMP1 may be formed simultaneously. In a process of forming holes penetrating an insulating layer 183, after a gate pad is exposed, an etching speed of holes for forming the contact plugs CCP may decrease. In contrast, an etching speed of holes for forming the first dummy plug DMP1 may not decrease until a substrate 103 is exposed. Therefore, a level of lower surfaces of the contact plugs CCP may be higher than a level of gate pads, and a level of a lower surface of the first dummy plug DMP1 may be lower than a level of an upper surface of a lowest gate pad among the gate pads. An etching process may be stopped before the substrate 103 is exposed. In this case, the level of the lower surface of the first dummy plug DMP1 may be lower than the level of the upper surface of the lowest gate pad among the gate pads, and the first dummy plug DMP1 may have a lower surface spaced apart from the upper surface of the substrate 103.

Even though the first dummy plug DMP1 is not in direct contact with the substrate 103, heat may be conducted to the substrate 103 through an adjacent insulating layer 183. Even though there is no direct contact between the substrate 103 and the first dummy plug DMP1, a heat conduction path may be secured, and effective heat dissipation may still be achieved.

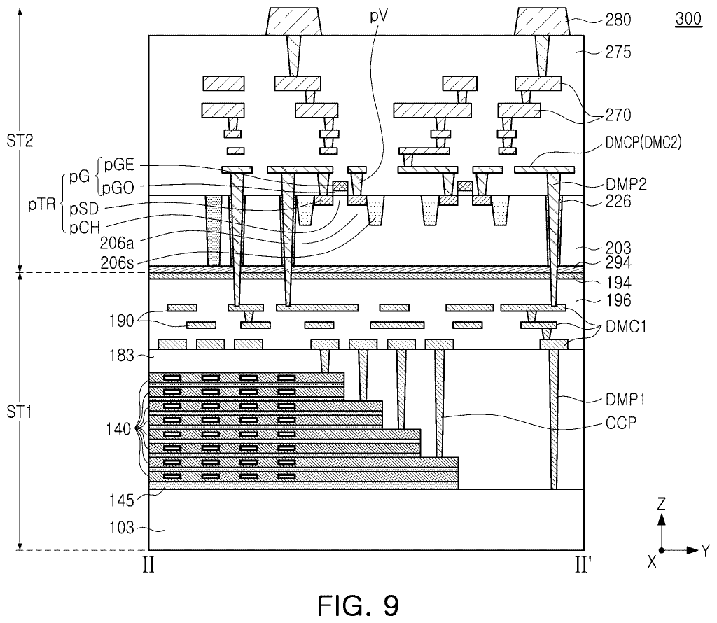

FIG. 9 is a vertical cross-sectional view along line II-II′ of a semiconductor device according to an embodiment.

Referring to FIG. 9, it can be understood that a semiconductor device 300 has a structure similar to that of the semiconductor device 100 illustrated in FIGS. 4 to 7, except that there is no dummy via DMV connecting a second dummy interconnection pad DMCP and a semiconductor body 203. Therefore, description of the semiconductor device 100 illustrated in FIGS. 4 to 7 may be combined with description of the semiconductor device 300 according to the present embodiment, unless otherwise stated.

A second structure ST2 may have a second dummy interconnection structure DMC2 embedded in an upper insulating structure 275 on a semiconductor body 203. The second dummy interconnection structure DMC2 may include a dummy interconnection pad DMCP having a lower surface contacting an upper surface of a second dummy plug DMP2. The dummy interconnection pad DMCP may be disposed in a lowermost layer in the second dummy interconnection structure DMC2. In this case, the lower surface of the dummy interconnection pad DMCP may be spaced apart from an upper surface of the semiconductor body 203.

Even though a second dummy via DMV is not in direct contact with the semiconductor body 203, heat may be transferred to the dummy interconnection pad DMCP through an adjacent upper insulating structure 275. The dummy interconnection pad DMCP may be connected to the second dummy plug DMP2, the second dummy plug DMP2 may be connected to a first dummy interconnection structure DMC1, the first dummy interconnection structure DMC1 may be connected to a first dummy plug DMP1, and the first dummy plug DMP1 may be connected to a substrate 103. Through this, heat generated in the semiconductor body 203 may be conducted to the substrate 103 in a first structure ST1. Even though there is no direct contact between the semiconductor body 203 and the dummy interconnection pad DMCP, a heat conduction path may be secured, and effective heat dissipation may still be achieved.

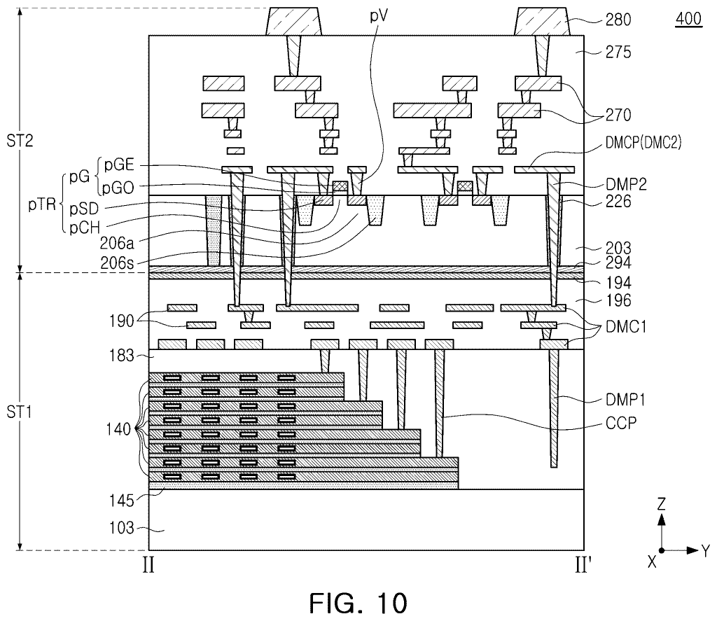

FIG. 10 is a vertical cross-sectional view along line II-II′ of a semiconductor device according to an embodiment.

Referring to FIG. 10, it can be understood that a semiconductor device 400 has a structure similar to that of the semiconductor device 100 illustrated in FIGS. 4 to 7, except that a first dummy plug DMP1 is not in direct contact with a substrate 103 and there is no dummy via DMV connecting a second dummy interconnection pad DMCP and a semiconductor body 203. Therefore, description of the semiconductor device 100 illustrated in FIGS. 4 to 7 may be combined with description of the semiconductor device 400 according to the present embodiment, unless otherwise stated.

In an embodiment, contact plugs CCP and a first dummy plug DMP1 may be formed simultaneously. In a process of forming holes penetrating an insulating layer 183, after a gate pad is exposed, an etching speed of holes for forming the contact plugs CCP may decrease. In contrast, an etching speed of holes for forming the first dummy plug DMP1 may not decrease until a substrate 103 is exposed. An etching process may be stopped before the substrate 103 is exposed. The first dummy plug DMP1 may have a lower surface spaced apart from an upper surface of the substrate 103.

A second structure ST2 may have a second dummy interconnection structure DMC2 embedded in an upper insulating structure 275 on a semiconductor body 203. The second dummy interconnection structure DMC2 may include a dummy interconnection pad DMCP having a lower surface contacting an upper surface of a second dummy plug DMP2. The dummy interconnection pad DMCP may be disposed in a lowermost layer in the second dummy interconnection structure DMC2. In this case, the lower surface of the dummy interconnection pad DMCP may be spaced apart from an upper surface of the semiconductor body 203.

An insulating spacer 226 spaced apart from the substrate 103 and the semiconductor body 203, but penetrating through the semiconductor body 203 may be included, and the insulating spacer 226 may be in contact with the second dummy plug DMP2. Through the insulating spacer 226, heat of the semiconductor body 203 may be conducted to the second dummy plug DMP2. Even though there is no direct contact between the semiconductor body 203 and the dummy interconnection pad DMCP and no direct contact between the substrate 103 and the first dummy plug DMP1, a heat conduction path may be secured, and effective heat dissipation may still be achieved.

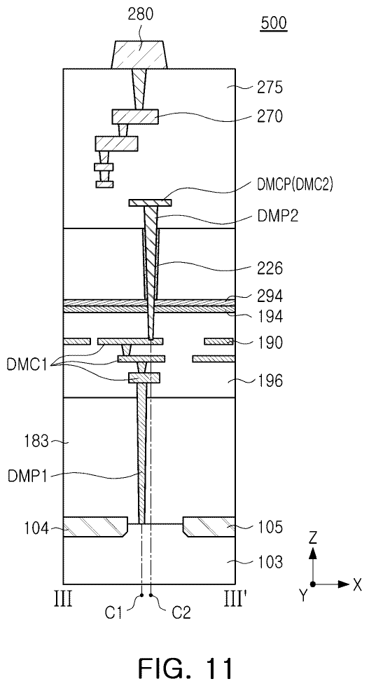

FIG. 11 is a vertical cross-sectional view along line III-III′ of a semiconductor device according to an embodiment.

Referring to FIG. 11, it can be understood that a semiconductor device 500 has a structure similar to that of the semiconductor device 100 illustrated in FIGS. 4 to 7, except that a first dummy plug DMP1 and a second dummy plug DMP2 do not overlap in the vertical direction (Z-direction). Therefore, description of the semiconductor device 100 illustrated in FIGS. 4 to 7 may be combined with description of the semiconductor device 500 according to the present embodiment, unless otherwise stated.

A first dummy plug DMP1 and a second dummy plug DMP2 may be spaced apart when viewed in the vertical direction. A first dummy interconnection structure DMC1 may include at least one layer of interconnections and at least one via. Even though not overlapping in the vertical direction, a substrate 103 and the first dummy plug DMP1 may be in contact. The first dummy plug DMP1 may be designed to contact a point advantageous for heat dissipation in the substrate 103, and the second dummy plug DMP2 may be designed to contact a point with a lot of heat generation in a semiconductor body 203. The semiconductor device 500 may have a design structure efficient for heat dissipation, and the first and second dummy plugs DMP1 and DMP2 may be formed regardless of arrangement of interconnection structures.

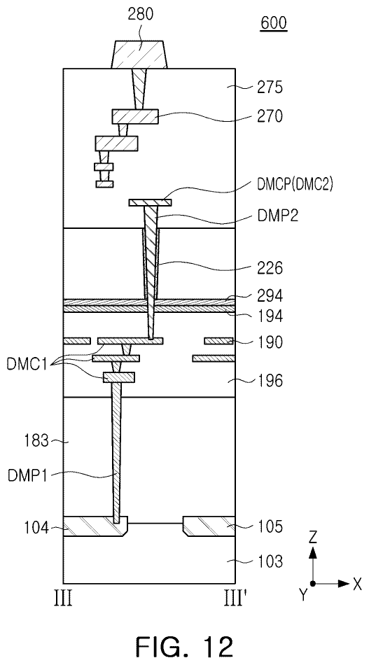

FIG. 12 is a vertical cross-sectional view along line III-III′ of a semiconductor device according to an embodiment.

Referring to FIG. 12, it can be understood that a semiconductor device 600 has a structure similar to that of the semiconductor device 100 illustrated in FIGS. 4 to 7, except that a first dummy plug DMP1 is in contact with a first element isolation pattern 104. Therefore, description of the semiconductor device 100 illustrated in FIGS. 4 to 7 may be combined with description of the semiconductor device 600 according to the present embodiment, unless otherwise stated.

A first dummy plug DMP1 and a second dummy plug DMP2 may be spaced apart when viewed in the vertical direction. Referring to FIGS. 2 and 4 to 7, a portion of an upper surface of a first element isolation pattern 104 may be in contact with lower surfaces of bit lines BL of a vertical conductive pattern 160. Since the first dummy plug DMP1 may be spaced apart from the second dummy plug DMP2 in the vertical direction (Z-direction), and may be in contact with the first element isolation pattern 104, a portion of the upper surface of the first element isolation pattern 104 may be in contact with a lower surface of the first dummy plug DMP1. The first dummy plug DMP1 may be spaced apart from a substrate 103, and may be in contact with the first element isolation pattern 104 on the substrate 103. The substrate 103 may be in contact with the first element isolation pattern 104, and the first element isolation pattern 104 may be in contact with the first dummy plug DMP1. Heat of the semiconductor body 203 may be conducted to the first dummy plug DMP1. Heat conducted to the first dummy plug DMP1 may be conducted to the substrate 103 via the first element isolation pattern 104. Even though there is no direct contact between the substrate 103 and the first dummy plug DMP1, a heat conduction path may be secured, and effective heat dissipation may still be achieved.

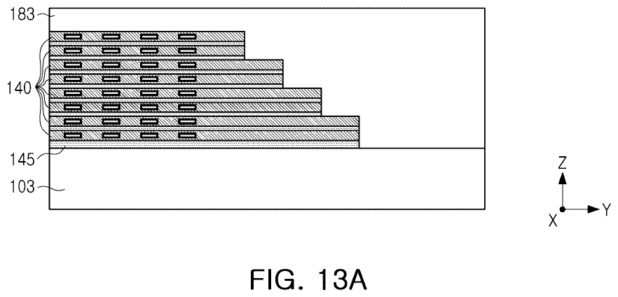

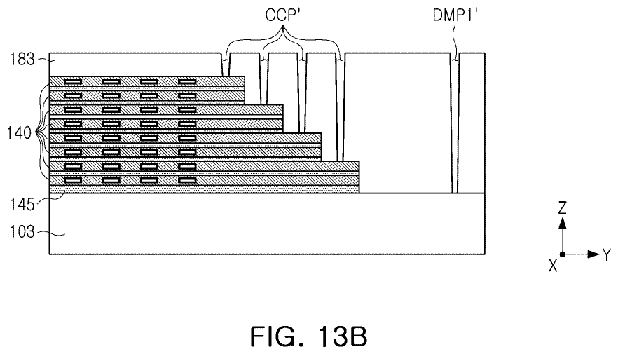

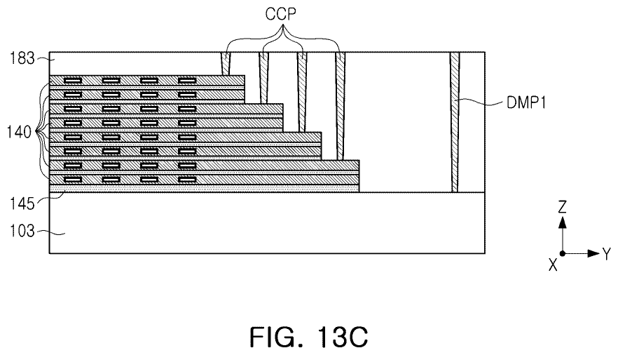

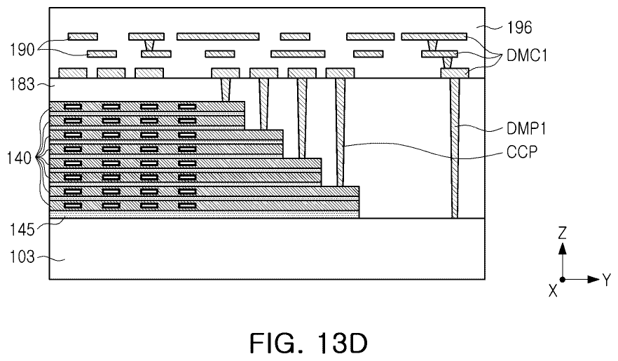

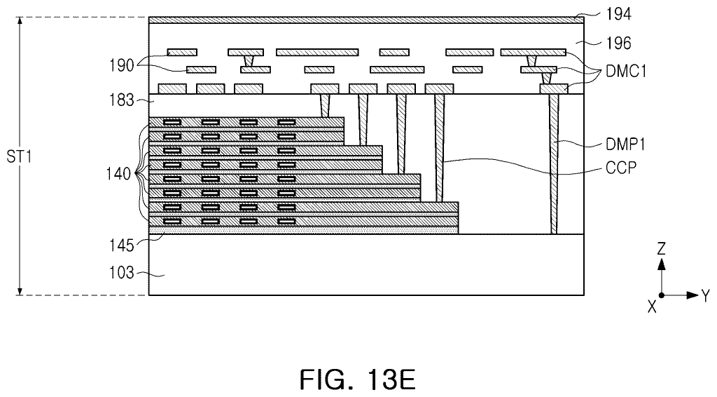

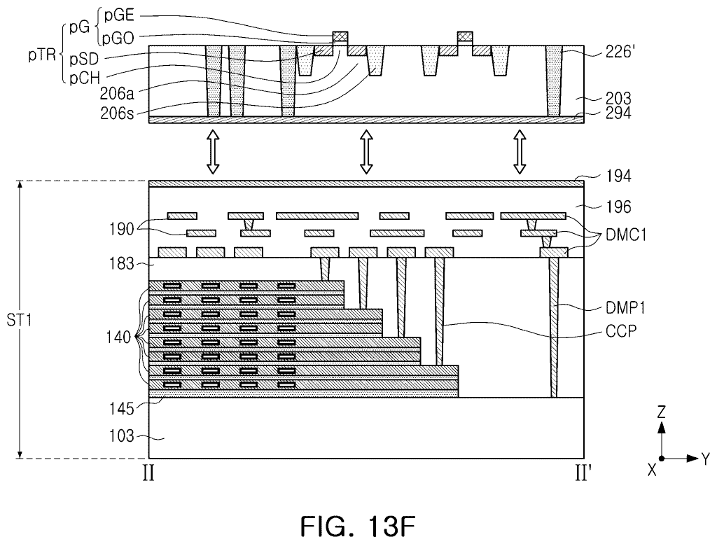

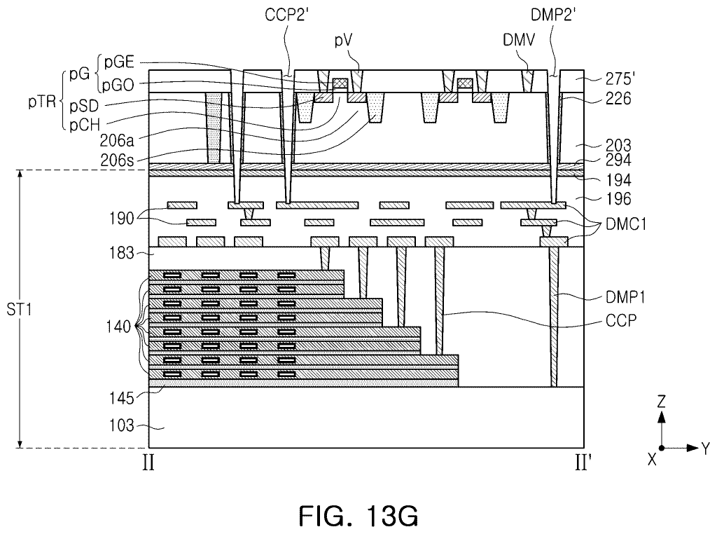

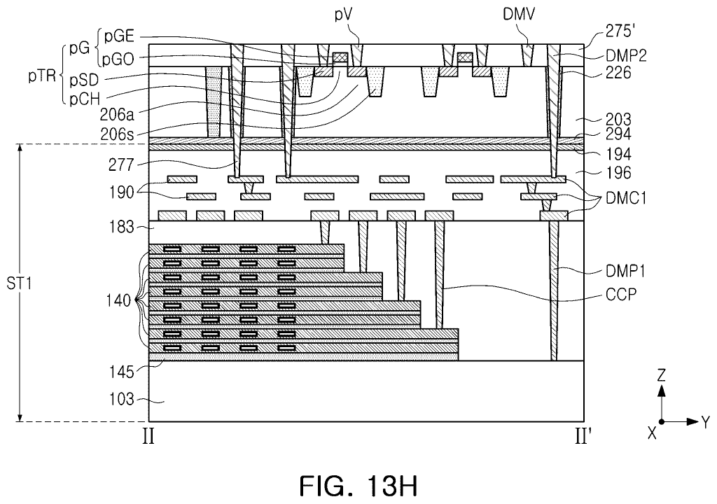

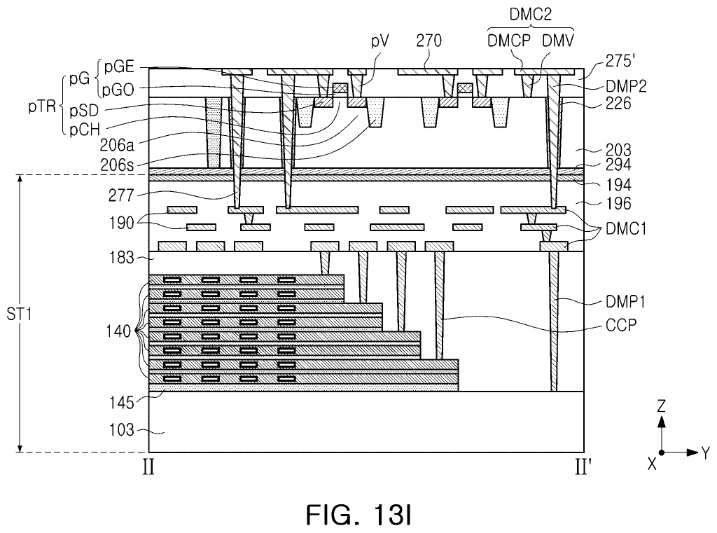

FIGS. 13A to 13I are cross-sectional views schematically illustrating a manufacturing process of a semiconductor device according to an embodiment. FIGS. 13A to 13I illustrate an embodiment of a manufacturing method for manufacturing the semiconductor device of FIGS. 4 to 7, and illustrate cross-sections corresponding to FIG. 6A.

Referring to FIG. 13A, a memory cell structure and an insulating layer 183 may be formed on a substrate 103.

Referring to FIG. 3 and FIG. 13A, gate electrodes 140 may be stacked vertically spaced apart from each other on a memory cell array region R1, and may extend from the memory cell array region R1 to a stepped region R2 at different lengths to form a step-shaped stepped structure. The gate electrodes 140 may form a stepped structure between the gate electrodes 140 spaced apart in the third direction (Z-direction) in the second direction (Y-direction). Due to the stepped structure, in the gate electrodes 140, a gate electrode 140 located at a lower level may extend to be longer than a gate electrode 140 located at an upper level, such that a portion of an upper surface of the gate electrode 140 located at a lower level is in contact with an interlayer insulating layer 145. In an example, a stepped structure may be formed by a second gate electrode, a fourth gate electrode, and a sixth gate electrode, disposed below an uppermost gate electrode, among the gate electrodes 140, a stepped structure may be formed by overlapping a third gate electrode disposed below the uppermost gate electrode with the second gate electrode, and overlapping a fifth gate electrode disposed below the uppermost gate electrode with the fourth gate electrode. However, the present inventive concept is not limited thereto, and each of the gate electrodes 140 disposed below the uppermost gate electrode may form a stepped structure, and for example, the third gate electrode disposed below the uppermost gate electrode may extend to be longer than the second gate electrode disposed below the uppermost gate electrode to form a stepped structure.

The insulating layer 183 may be formed on the substrate 103 to cover vertical conductive patterns 160 and capacitor structures 150 and a portion of the substrate 103.

Referring to FIG. 13B, a portion of the insulating layer 183 may be etched to form contact via holes CCP′ exposing a gate pad. In addition, a portion of the insulating layer 183 may be etched to form first dummy via holes DMP1′ exposing the substrate 103 A photoresist may be formed on the insulating layer 183. The photoresist may be formed to partially cover the insulating layer 183. An exposure and development process may be performed on the photoresist. A portion of the insulating layer 183 may be etched using the photoresist as an etching mask on an upper surface of the contact via holes CCP′ and the first dummy via holes DMP1′. The insulating layer 183 in a region corresponding to the contact via holes CCP′ and the first dummy via holes DMP1′ may be partially removed. A portion of the insulating layer 183 may be etched to expose gate pads by the contact via holes CCP′. The substrate 103 may be exposed by the first dummy via holes DMP1′.

In an embodiment, the contact via holes CCP′ and the first dummy via holes DMP1′ may be formed simultaneously. In a process of forming the contact via holes CCP′ and the first dummy via holes DMP1′ penetrating the insulating layer 183, an etching speed of the contact via holes CCP′ may decrease after the gate pad is exposed. In contrast, an etching speed of the first dummy via holes DMP1′ may not decrease until the substrate 103 is exposed.

Therefore, a level of lower surfaces of the contact via holes CCP′ may be higher than a level of the gate pads, and a level of lower surfaces of the first dummy via holes DMP1′ may be lower than a level of an upper surface of a lowest gate pad among the gate pads.

The photoresist may be removed by performing a strip or ashing process. The photoresist may be removed, for example, using a solution containing H₂O₂, H₂SO₄, or the like, or using a gas such as O₂, N₂, H₂, or the like. However, the process of forming the contact via holes CCP′ and the first dummy via holes DMP1′ is not limited thereto.

Referring to FIG. 13C, the contact via holes (CCP′ of FIG. 13B) may be filled with a conductive material to form contact plugs CCP. In addition, the first dummy via holes DMP1′ may be filled with a conductive material to form first dummy plugs DMP1.

The gate pads may be exposed by the contact via holes (CCP′ of FIG. 13B) on an upper surface of the second gate electrode, an upper surface of the fourth gate electrode, and an upper surface of the sixth gate electrode, disposed below the uppermost gate electrode among the gate electrodes 140. The conductive material may be formed in the contact via holes (CCP′ of FIG. 13B) to form the contact plugs CCP contacting the gate pads.

The conductive material may include, for example, a metal material including copper (Cu), aluminum (Al), silver (Ag), tin (Sn), gold (Au), nickel (Ni), lead (Pb), titanium (Ti), or an alloy thereof. However, the present inventive concept is not limited thereto.

The conductive materials may be formed in the contact via holes (CCP′ in FIG. 13B) and a planarization process may be performed to form the contact plugs CCP. In this case, the planarization process may be performed through a planarization process such as a grinding process, a chemical mechanical planarization (CMP) process, or the like. Through the CMP process, the insulating layer 183, the contact plugs CCP, and the first dummy plugs DMP1 may form a coplanar surface.

When viewed in the first horizontal direction (X-direction), the first dummy plugs DMP1 may be formed to be disposed to be parallel to the contact plugs CCP but spaced apart in the second direction (Y-direction). The first dummy plugs DMP1 may be formed to be spaced apart from the contact plugs CCP. The first dummy plug DMP1 may be formed to have an interval, equal to an interval between the contact plugs CCP, but the intervals may not be the same. The first dummy plug DMP1 may be formed to contact the substrate 103.

Referring to FIG. 13D, an insulating structure 196 covering the contact plugs CCP and the first dummy plugs DMP1, and an interconnection structure 190 and a first dummy interconnection structure DMC1 may be formed.

The insulating structure 196 may include the interconnection structures 190 and the first dummy interconnection structure DMC1, embedded therein. The insulating structure 196 may be composed of a plurality of layers. Each of the layers may include a portion composed of an insulating material, and interconnections composed of a conductive material. Depending on a process, a boundary between insulating materials disposed between the layers may not be distinct. Forming the insulating structure 196, the interconnection structure 190, and the first dummy interconnection structure DMC1 may include sequentially forming the plurality of layers. Forming each layer of the insulating structure 196 may include performing a process of forming the insulating material and the conductive material and performing a planarization process in plural. The insulating structure 196 may be formed by performing an exposure process and a development process to form a via hole penetrating each layer, and patterning a metal material on each layer using a plating process.

The insulating structure 196 may include a plurality of insulating layers stacked in the vertical direction (Z-direction).

The interconnection structure 190 and the first dummy interconnection structure DMC1 may include a metal material including, for example, copper (Cu), aluminum (Al), silver (Ag), tin (Sn), gold (Au), nickel (Ni), lead (Pb), titanium (Ti), or an alloy thereof. However, the present inventive concept is not limited thereto.

The insulating structure 196, and the interconnection structures 190 and the first dummy interconnection structure DMC1, embedded in the insulating structure 196, may be formed on the contact plugs CCP, the first dummy plugs DMP1, and the insulating layer 183. The contact plugs CCP may be connected to the interconnection structures 190. The first dummy plug DMP1 may be connected to the first dummy interconnection structure DMC1. Upper surfaces of the contact plugs CCP may be in contact with lower surfaces of lowermost interconnection structures 190 among the interconnection structures 190. The first dummy plug DMP1 may be in contact with a lowermost first dummy interconnection structure DMC1 among the first dummy interconnection structures DMC1.

Referring to FIG. 13E, a first bonding insulating layer 194 may be formed on an upper surface of the insulating structure 196.

The first bonding insulating layer 194 may be further formed on the insulating structure 196. The first bonding insulating layer 194 may be formed along the upper surface of the insulating structure 196. The first bonding insulating layer 194 may include, for example, at least one of SiO, SiN, SiCN, SiOC, SiON, or SiOCN.

Referring to FIGS. 13F and 13G, a second bonding insulating layer 294 may be formed on a lower surface of a semiconductor body 203. The first bonding insulating layer 194 of a first structure ST1 and the second bonding insulating layer 294 of a second structure may be bonded.

The second bonding insulating layer 294 may be further formed below the semiconductor body 203. The second bonding insulating layer 294 may be formed along the lower surface of the semiconductor body 203. The second bonding insulating layer 294 may include, for example, at least one of SiO, SiN, SiCN, SiOC, SiON, or SiOCN.

The first structure ST1 and the semiconductor body 203 may be bonded by bonding the first bonding insulating layer 194 and the second bonding insulating layer 294. The bonding of the first bonding insulating layer 194 and the second bonding insulating layer 294 may be, for example, a dielectric-dielectric bonding such as SiCN—SiCN bonding. The first structure ST1 and the semiconductor body 203 may be bonded only by the bonding of the first and second bonding insulating layers 194 and 294.

The semiconductor body 203 including peripheral transistors pTR constituting a peripheral circuit on the semiconductor body 203 may be bonded. The semiconductor body 203 may include a plurality of insulating trenches 226′.

After a bonding surface below the first structure ST1 and the semiconductor body 203 is plasma activated, precise position alignment may be performed. Thereafter, bonding may be performed by applying pressure at a high temperature. An annealing process may be added after bonding to promote diffusion bonding of an interface. However, the present inventive concept is not limited thereto.

Referring to FIG. 13G, an upper insulating layer 275′ covering the peripheral transistors pTR of a second structure ST2 may be formed, and peripheral vias pV connected to the peripheral transistors pTR, a through-via hole CCP2′, and a second dummy via hole DMP2′ may be formed.

The upper insulating layer 275′ covering the peripheral transistors pTR of the second structure ST2 may be formed, and the peripheral via pV may be formed. Forming the upper insulating layer 275′ and the peripheral via pV may include forming an insulating material and performing a planarization process. The peripheral via pV may be formed by performing an exposure process and a development process to form a via hole, and filling a metal material using a plating process.

The through-via hole CCP2′ may be formed by sequentially etching the upper insulating layer 275′, a portion of the insulating trenches 226′, the second bonding insulating layer 294, the first bonding insulating layer 194, and a portion of the insulating structure 196.

A photoresist may be formed on the upper insulating layer 275′. The photoresist may be formed to cover a portion of the upper insulating layer 275′. An exposure and development process may be performed on the photoresist. Using the photoresist as an etching mask, a portion of the upper insulating layer 275′ may be etched on the upper surface of the through-via holes CCP2′ and the second dummy via holes DMP2′. The upper insulating layer 275′ in a region corresponding to the through-via holes CCP2′ and the second dummy via holes DMP2′ may be partially removed.

Using the photoresist as an etching mask on the upper surface of the through-via holes CCP2′ and the second dummy via hole DMP2′, a portion of the insulating trenches 226′ may be etched. The portion of the insulating trenches 226″ in a region corresponding to the through-via holes CCP2′ and the second dummy via hole DMP2′ may be partially removed.

Using the photoresist as an etching mask on the upper surface of the through-via holes CCP2′ and the second dummy via hole DMP2′, a portion of the first and second bonding insulating layers 194 and 294 may be etched. The first and second bonding insulating layers 194 and 294 in a region corresponding to the through-via holes CCP2′ and the second dummy via hole DMP2′ may be partially removed.

A portion of the insulating structure 196 may be etched using the photoresist as an etching mask on the upper surface of the through-via holes CCP2′ and the second dummy via hole DMP2′. The insulating structure 196 in a region corresponding to the through-via holes CCP2′ and the second dummy via hole DMP2′ may be partially removed. By etching a portion of the insulating structure 196, the interconnection structures 190 may be exposed by the through-via holes CCP2′. The first dummy interconnection structure DMC1 may be exposed by the second dummy via hole DMP2′.

The photoresist may be removed by performing a strip or ashing process. The photoresist may be removed using a solution containing H₂O₂, H₂SO₄, or the like, or using a gas such as O₂, N₂, H₂, or the like. However, the process of forming the through-via hole CCP2′ and the second dummy via hole DMP2′ is not limited thereto.

Referring to FIG. 13H, a through-via that penetrates an insulating layer, an insulating trench in a semiconductor body, and bonding insulating layers, may be formed.

A conductive material may be formed in the through-via holes (CCP2′ of FIG. 13G), such that through-plugs 277 contacting the interconnection structures 190 may be formed. A conductive material may be formed in the second dummy via holes (CMP2′ of FIG. 13G), such that a second dummy plug DMP2 contacting the first dummy interconnection structure DMC1 may be formed.

The conductive material may include, for example, a metal material including copper (Cu), aluminum (Al), silver (Ag), tin (Sn), gold (Au), nickel (Ni), lead (Pb), titanium (Ti), or an alloy thereof. However, the present inventive concept is not limited thereto.

The conductive materials may be formed in the through-via holes (CCP2′ of FIG. 13G) and a planarization process may be performed to form the through-plugs 277. In this case, the planarization process may be performed through a planarization process such as a grinding process, a chemical mechanical planarization (CMP) process, or the like. Through the CMP process, the upper insulating layer 275′, the contact plugs CCP, and the second dummy plugs DMP2 may form a coplanar surface.

Referring to FIG. 13I, a conductive material may be filled in the through-via, and second contact plugs and second dummy plugs may be formed. In addition, an insulating layer and interconnection patterns covering the second contact plugs and the second dummy plugs may be formed.

Referring to FIG. 6A and FIG. 13I together, an upper insulating structure 275 may include peripheral interconnection structures 270 and a second dummy interconnection structure DMC2. The upper insulating structure 275 may be composed of a plurality of layers. Each of the layers may include a portion composed of an insulating material, and interconnections composed of a conductive material. Depending on a process, a boundary between insulating materials disposed between the layers may not be distinct. Forming the upper insulating structure 275, the peripheral interconnection structures 270, and the second dummy interconnection structure DMC2 may include sequentially forming the plurality of layers. Forming each layer of the upper insulating structure 275 may include performing a process of forming the insulating material and the conductive material and performing a planarization process in plural. The upper insulating structure 275 may be formed by performing an exposure process and a development process to form a via hole penetrating each layer, and patterning a metal material on each layer using a plating process.

The upper insulating structure 275 may include a plurality of insulating layers stacked in the vertical direction (Z-direction).

The peripheral interconnection structures 270, the second dummy interconnection structures DMC2 may include, for example, a metal material including copper (Cu), aluminum (Al), silver (Ag), tin (Sn), gold (Au), nickel (Ni), lead (Pb), titanium (Ti), or an alloy thereof. However, the present inventive concept is not limited thereto.

The upper insulating structure 275, the peripheral interconnection structures 270 embedded in the upper insulating structure 275, and the second dummy interconnection structure DMC2 may be formed on the through-plugs 277 and the second dummy plugs DMP2 and the upper insulating layer (275′ of FIG. 13H). The through-plugs 277 may be connected to the interconnection structures 190. The second dummy plug DMP2 may be connected to the second dummy interconnection structure DMC2. The upper surface of the through-plugs 277 may be in contact with a lower surface of lowermost interconnection structures 270 among the interconnection structures 270. The second dummy plug DMP2 may be in contact with a lowermost second dummy interconnection structure DMC2 among the second dummy interconnection structures DMC2.

According to embodiments, dummy plugs may be respectively disposed in a first structure and a second structure, and the dummy plugs may be disposed to be connected to each other, such that heat generated in the first structure may be effectively transferred to the second structure. Through this, the present inventive concept may disperse the heat over a wider area, to improve heat dissipation efficiency, to alleviate an overheating problem of a three-dimensional semiconductor device, and to secure long-term reliability.

Various advantages and effects of the present inventive concept are not limited to the above-described contents, and will be more easily understood in the process of explaining specific embodiments.

While example embodiments have been illustrated and described above, it will be apparent to those skilled in the art that modifications and variations could be made without departing from the scope of the present inventive concept as defined by the appended claims.

What is claimed is:

1. A semiconductor device comprising:
a first structure including a substrate; and
a second structure vertically overlapping the first structure and bonded to the first structure,
wherein the first structure includes:
a memory cell structure on the substrate;
a first dummy plug spaced apart from the memory cell structure, electrically isolated from the memory cell structure, and extending in a vertical direction, on the substrate; and
a first dummy interconnection structure connected to the first dummy plug, on the first dummy plug, and
the second structure includes:
a semiconductor body;
a second dummy plug penetrating the semiconductor body and connected to the first dummy interconnection structure; and
an insulating spacer between the semiconductor body and the second dummy plug.

2. The semiconductor device of claim 1, wherein:
the substrate is a semiconductor substrate, and
the first dummy plug is in contact with the substrate.

3. The semiconductor device of claim 2, wherein the first dummy plug is at a lower level than an upper surface of the substrate, and has a lower surface contacting the substrate.

4. The semiconductor device of claim 3, wherein:
a side surface of the first dummy plug includes a side surface portion at a lower level than the upper surface of the substrate, and
the side surface portion of the side surface of the first dummy plug is in contact with the substrate.

5. The semiconductor device of claim 1, wherein:
the second structure further includes an upper insulating structure on the semiconductor body, and a second dummy interconnection structure embedded in the upper insulating structure, and
the second dummy interconnection structure includes a dummy interconnection pad having a lower surface contacting an upper surface of the second dummy plug, and a dummy via connecting the dummy interconnection pad to the semiconductor body.

6. The semiconductor device of claim 1, wherein:
the second structure further includes an upper insulating structure on the semiconductor body, and a second dummy interconnection structure embedded in the upper insulating structure,
the second dummy interconnection structure includes a dummy interconnection pad having a lower surface contacting an upper surface of the second dummy plug, and
the lower surface of the dummy interconnection pad is spaced apart from an upper surface of the semiconductor body.

7. The semiconductor device of claim 6, wherein the first dummy plug has a lower surface spaced apart from an upper surface of the substrate.

8. The semiconductor device of claim 1, wherein the second dummy plug is spaced apart from the semiconductor body by the insulating spacer.

9. The semiconductor device of claim 1, wherein:
the second dummy plug has a width decreasing in a direction from the second structure toward the first structure,
a width of an upper surface of the second dummy plug is between about 50 nm and about 80 nm, and
a width of a lower surface of the second dummy plug is between about 30 nm and about 45 nm.

10. The semiconductor device of claim 1, wherein:
the first structure includes a first bonding insulating layer, and
the second structure includes a second bonding insulating layer bonded to the first bonding insulating layer of the first structure.

11. A semiconductor device comprising:
a first structure including a semiconductor substrate; and
a second structure on the first structure and including a semiconductor body,
wherein the first structure includes:
a memory cell structure on the semiconductor substrate;
a first routing pattern on the memory cell structure, electrically connected to the memory cell structure, and extending in a vertical direction;
a first routing interconnection electrically connected to the first routing pattern, on the first routing pattern;
a first heat conduction pattern spaced apart from the memory cell structure in a horizontal direction, and extending in the vertical direction; and
a first heat conduction interconnection connected to the first heat conduction pattern, on the first heat conduction pattern,
the second structure includes:
an upper insulating structure on the semiconductor body;
a second routing interconnection embedded in the upper insulating structure;
a second routing pattern extending in the vertical direction, below the second routing interconnection;
a second heat conduction interconnection embedded in the upper insulating structure and spaced apart from the second routing interconnection in the horizontal direction; and
a second heat conduction pattern extending in the vertical direction, below the second heat conduction interconnection,
the second routing pattern penetrates the semiconductor body and is connected to the first routing interconnection to form an electric signal transmission path, and
the second heat conduction pattern penetrates the semiconductor body and is connected to the first heat conduction interconnection to form a heat conduction path.

12. The semiconductor device of claim 11, wherein:
the first heat conduction pattern is connected to the semiconductor substrate, and is longer in the vertical direction than the first routing pattern, and
a width of a lower surface of the first heat conduction pattern is smaller than a width of a lower surface of the first routing pattern.

13. The semiconductor device of claim 11, wherein:
the second structure further includes a peripheral transistor on the semiconductor body, and a routing via electrically connected to the peripheral transistor, and
the second routing interconnection is in contact with the second routing pattern, and is in contact with the routing via.

14. The semiconductor device of claim 13, wherein:
the second structure further includes a heat conduction via contacting the semiconductor body, and
the second heat conduction interconnection is in contact with the second heat conduction pattern, and is in contact with the heat conduction via.

15. A semiconductor device comprising:
a first structure including a semiconductor substrate; and
a second structure vertically overlapping the first structure and bonded to the first structure,
wherein the first structure includes:
channel structures extending in a first horizontal direction on the semiconductor substrate and spaced apart from each other in a second horizontal direction, intersecting the first horizontal direction and in a vertical direction, intersecting the first horizontal direction and the second horizontal direction;
bit lines extending in the vertical direction on the semiconductor substrate, spaced apart from each other in the second horizontal direction, and contacting a first end portion of each of the channel structures;
information storage structures contacting second end portions of the channel structures opposing the first end portions of the channel structures;
gate electrodes surrounding the channel structures spaced apart from each other in the second horizontal direction, extending in the second horizontal direction, and including gate pads in a stepped structure;
a first dummy plug contacting the semiconductor substrate and extending in the vertical direction; and
a first dummy interconnection structure overlapping the first dummy plug in the vertical direction, and connected to the first dummy plug, and
the second structure includes:
a semiconductor body;
an upper insulating structure on the semiconductor body;
a second dummy interconnection structure embedded in the upper insulating structure;
a dummy via extending in the vertical direction and contacting an upper surface of the semiconductor body, below the second dummy interconnection structure; and
a second dummy plug extending in the vertical direction and penetrating the semiconductor body to be connected to the first dummy interconnection structure, below the second dummy interconnection structure.

16. The semiconductor device of claim 15, wherein the second structure further includes an insulating spacer disposed between the second dummy plug penetrating the semiconductor body and the semiconductor body.

17. The semiconductor device of claim 15, wherein the first dummy plug and the second dummy plug are spaced apart from each other in the vertical direction.

18. The semiconductor device of claim 15, wherein the first structure further includes a device isolation structure disposed in the semiconductor substrate and extending in the second horizontal direction,
a portion of the upper surface of the device isolation structure is in contact with lower surfaces of the bit lines, and
a portion of the upper surface of the device isolation structure is in contact with a lower surface of the first dummy plug.

19. The semiconductor device of claim 15, wherein a level of a lower surface of the first dummy plug is lower than a level of an upper surface of a lowermost gate pad among the gate pads, and
the first dummy plug has a lower surface spaced apart from an upper surface of the semiconductor substrate.

20. The semiconductor device of claim 15, wherein a portion of the first dummy plug partially penetrates the semiconductor substrate to have a first groove having a first depth, and
a portion of the dummy via partially penetrates the semiconductor body to have a second groove having a second depth, shallower than the first depth.
